(19) United States
(12) Patent Application Publication
(10) Pub. No.: US 2007/0075057 A1
(43) Pub. Date: Apr. 5, 2007

(54) Method for fine tuning circuit and controlling impedance with laser process

(76) Inventors: Yi-Hsi Chen, Pingjhen City (TW); Chih-Chuan Lin, Sinfong Township (TW)

Correspondence Address: LIN & ASSOCIATES INTELLECTUAL PROPERTY, P.O. BOX 2339, SARATOGA, CA, 95070-0339, US

(21) Appl. No.: 11/207,412

(22) Filed: Aug. 19, 2005

(51) Int. Cl. B23K 26/00; H01L 21/44

(52) U.S. Cl. 219/121.69; 219/121.64; 438/662

(57) ABSTRACT

A method for actively controlling he fine-tuning and impedance matching using a laser process is provided, including the use of a laser process equipment, a monitor device, and a feedback controller. The laser process equipment is for performing laser soldering or laser etching. The monitor device is for monitoring the target metrics of the target circuits. The feedback controller is for receiving the feedback from the monitor device and issuing control signals to the laser process equipment. The method includes the following steps: (a) loading the target high frequency circuit to the laser process equipment for laser process; (b) monitoring the impedance of the circuit or the transmission/reflection signals and outputting a measured value; (c) determining whether the measured value equal to target value, computing an error signal as the difference between measured value and target value; if not, sending control signals to laser process equipment according to the error signal and proceeding to step (d), otherwise, proceeding to step (e); (d) performing the laser process on the target circuit according to the control signal, returning to step (c); and (e) unloading the target high frequency circuit from the laser process equipment.

### FIELD OF THE INVENTION

The present invention generally relates to a method for fine tuning circuits, and more specifically to a method for using laser processes to control the impedance of the circuit.

### BACKGROUND OF THE INVENTION

Impedance is defined as the combined effect of capacitance, inductance, and resistance that a circuit offers a signal at a given frequency. When high-frequency signals are carried on transmission lines of any significant length, care must be taken that the transmission medium is matched to its terminations. The source and load impedances should equal the characteristic impedance of the transmission line, as this minimizes signal reflections. The presence of impedance discontinuities or mismatches will degrade the amplitude and phase accuracy, as well as the temporal fidelity of the signal. In short, impedance matching is necessary to make the RF signals meaningful, and thus is considered the lifeblood of RF circuit design. High frequency systems are among the most advanced RF systems—they are among the most difficult to set up and most maintain. On one hand, higher frequencies correspond to faster rates of transmission, which is undoubtedly a good thing for the user. Using such frequencies, however, presents a myriad of problems for the RF designer.

This is especially important for fiber optical communication devices. In general, the packaging form of laser diode and photodiode is large, and the impedance mismatch resulted from the deviation of the soldering process, article dimension and SMT (Surface Mount Technology) process is difficult to be controlled, especially for high frequency applications, such as 2.5 Gbps or higher. U.S. Pat. No. 4,381,441 disclosed a method for trimming a film resistor to determine the resistance value of the resistor.

Laser processes have been used in many aspects of semiconductor manufacturing processes, such as laser soldering and laser etching. Laser soldering is a highly precise and highly flexible process that can be easily repeated. The most significant advantage of laser soldering is the localization of heat input. Laser etching, on the other hand, is an environmental-friendly, highly flexible and inexpensive process. U.S. Pat. No. 5,742,025 disclosed a laser soldering process on the flexible circuit board between optical sub-assembly and rigid interconnect.

As impedance control is vital for the high frequency applications, it is imperative to develop an active impedance control method. As both laser soldering and laser etching processes are highly precise processes, it is important to exploit their applications in the impedance control of the RF circuits.

### SUMMARY OF THE INVENTION

The primary object of the present invention is to provide a method for fine-tuning circuits and active controlling impedance of the circuits. To achieve the object, the present invention provides a method employing an active control in a laser process on the key parts in the target circuit. The key parts, such as solder pad, copper circuit, and submount coating, of the target circuit requires precise impedance match to achieve good quality on transmission of the signal, especially for optical communication. Since a large deviation of the soldering quality will affect the performance of the transmission, the active control allows the user to fine tune the target circuit.

The method of the present invention includes the use of a laser process equipment, a monitor device, and a feedback controller. The laser process equipment, such as a high power diode or Nd:YAG/Nd:YVO4 laser or the second harmonic generation (SHG) and the third harmonic generation (THG) of the laser, is for performing laser soldering or laser etching. The monitor device, such as an impedance meter or transmission monitor, is for monitoring the target metrics of the target circuits. The feedback controller, such as a PC, is for receiving the feedback from the monitor device and issuing control signals to the laser process equipment. The method includes the following steps: (a) loading the target high frequency circuit to the laser process equipment for laser process; (b) monitoring the impedance of the circuit or the transmission/reflection signals and outputting a measured value; c) determining whether the measured value equal to target value, computing an error signal as the difference between measured value and target value; if not, sending control signals to laser process equipment according to the error signal and proceeding to step (d), otherwise, proceeding to step (e); (d) performing the laser process on the target circuit according to the control signal, returning to step (c); and (e) unloading the target high frequency circuit from the laser process equipment.

The foregoing and other objects, features, aspects and advantages of the present invention will become better understood from a careful reading of a detailed description provided herein below with appropriate reference to the accompanying drawings.

### BRIEF DESCRIPTION OF THE DRAWINGS

The present invention can be understood in more detail by reading the subsequent detailed description in conjunction with the examples and references made to the accompanying drawings, wherein:

FIG. 1 shows a schematic view of an active laser process system according to the invention; and

FIG. 2 shows a flowchart of the method of the present invention using the system shown in FIG. 1.

### DETAILED DESCRIPTION OF THE PREFERRED EMBODIMENTS

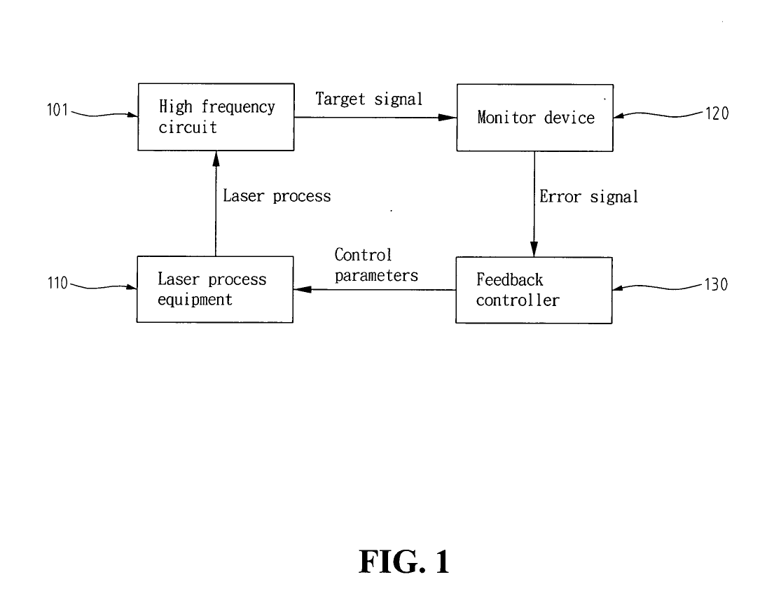

FIG. 1 shows a schematic view of an active laser process system, including a laser process equipment 110, a monitor device 120, and a feedback controller 130. Laser process equipment 110 can be of any type that is capable to perform laser soldering or laser etching on the target high frequency circuit, such as a high power diode or Nd:YAG/Nd:YVO4 laser or the SHG and THG of the laser. Monitor device 120 is for monitoring the target metrics of the target high frequency circuit for fine tuning. The target metrics can be impedance or the transmission/reflection signals. Monitor device 120 can be an impedance meter or transmission monitor. Feedback controller 130 is for receiving the feedback signals from monitor device 120 and issuing control signals to laser process equipment 110. Feedback controller can be a PC, or a microprocessor.

When a target circuit 101 is loaded to the system, monitor device 120 monitors the target signal of target circuit 101. Based on the measured signal, monitor device 120 sends an error signal to feedback controller 130, which, in turns, sends control signals and parameters to laser process equipment 110 to control the laser process. Laser process equipment 110 performs a laser process on target circuit 101 according to the control signals and parameters from feedback controller 120.

The aforementioned control signals and parameters depend on the laser process applied. In the case of laser soldering, the control signals and parameters may include laser power, pulse duration, spot size, wavelength of the laser, and repetition rate, and so on. In the case of laser etching, the control signals and parameters may include peak power, pulse duration, spot size, wavelength, and repetition rate.

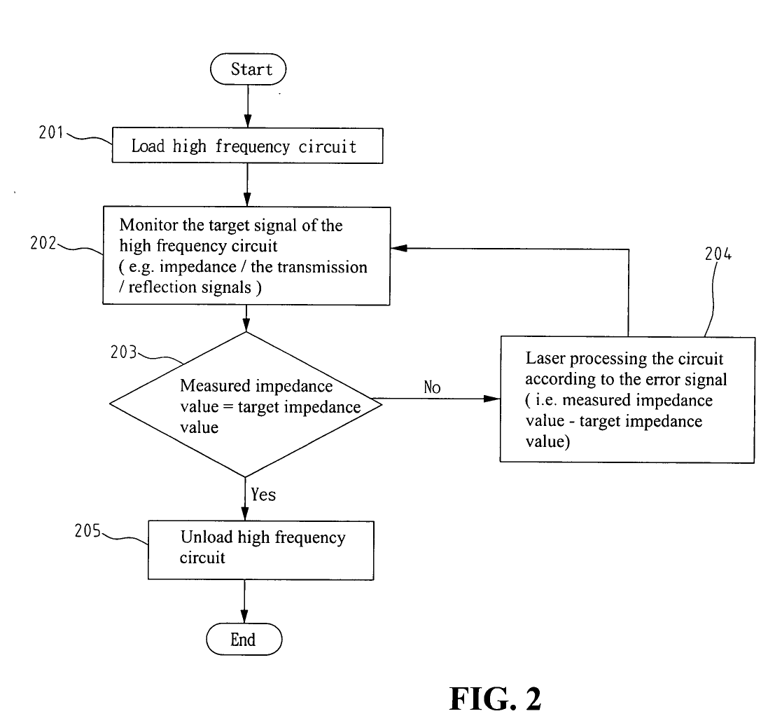

FIG. 2 shows a flowchart of the method of the present invention, including the following steps. Step 201 is to load a target high frequency circuit to laser process equipment 110. Step 202 is for monitor device 120 to monitor the target signal of target circuit 101. The target signal can be the impedance of the circuit or the transmission/reflection signals. In step 203, monitor device 120 compares the measured value of the target signal with the target value, and determines whether the target has been reached. If so, the process is complete and proceeds to step 205 to unload target circuit 101. Otherwise, the difference between the measured value and the target value is computed as the error signals, and control signals according the error signals sent to laser process equipment 110, and proceed to step 204. In step 204, laser process equipment 110 performs a laser process on target circuit 101 according to the control signal. Steps 202, 203, and 204 form a loop, which iterates until the measured value equals the target value.

In step 204, the laser process can be either a laser soldering process or a laser etching process. In the case of laser soldering, the control signals and parameters may include laser power, pulse duration, spot size, wavelength of the laser, and repetition rate, and so on. In the preferred embodiment, the laser power is preferably about 10 W, although it may range from 5 W to 50 W. The pulse duration is preferably about 100 ms, and may be from 20 ms to 2 s. The spot size has the diameter between 0.01 and 1 mm, preferably about 0.5 mm. The wavelength is 808 nm or 1064 nm. The repetition rate ranges from CW to 50 kHz, preferably CW or 10 kHz.

In the case of laser etching, the control signals and parameters may include peak power, pulse duration, spot size, wavelength, and repetition rate. In the preferred embodiment, the laser power is preferably about 10 kW, while it may range from 1 kW to 100 kW. The pulse duration is preferably 10 ns, and may be from 1 ns to 100 ns. The spot size has the diameter between 0.01 and 1 mm, preferably 0.05 mm. The wavelength is 532 nm or 1064 nm. The repetition rate ranges from 1 kHz to 50 kHz, preferably about 10 kHz.

The present invention provides a method for actively controlling the laser process to fine tune the circuit and impedance by using a flexible and highly precise laser process, a monitor device and a feedback controller. The use of monitor device and the feedback controller provides the interactivity so that the laser process can be applied and controlled to achieve the target characteristics.

Although the present invention has been described with reference to the preferred embodiments, it will be understood that the invention is not limited to the details described thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A method for fine tuning the circuit and impedance matching, by using a laser process equipment, a monitor device and a feedback controller, comprising the following steps of:
(a) loading a target high frequency circuit to said laser process equipment for laser process;
(b) using said monitor device to monitor the impedance of said target circuit or the transmission/reflection signals and outputting a measured value;
(c) using said feedback controller to determine whether said measured value equal to a target value and compute an error signal as the difference between said measured value and said target value; if not, sending control signals to said laser process equipment based on said error signals and proceeding to step (d), otherwise, proceeding to step (e);
(d) using said laser process equipment to perform a laser process on said target circuit according to said control signal, and returning to step (c); and
(e) unloading said target circuit from said laser process equipment.

2. The method as claimed in claim 1, wherein said laser process equipment is a high power diode laser equipment.

3. The method as claimed in claim 1, wherein said laser process equipment is a Nd:YAG/Nd:YVO4 laser or the SHG and THG of said laser equipment.

4. The method as claimed in claim 1, wherein said monitor device is an impedance meter.

5. The method as claimed in claim 1, wherein said feedback controller is a PC.

6. The method as claimed in claim 1, wherein said laser process is a laser soldering process.

7. The method as claimed in claim 6, wherein said control signals comprise information on laser power, pulse duration, spot size, wavelength, and repetition rate of the laser.

8. The method as claimed in claim 1, wherein said laser process is a laser etching process.

9. The method as claimed in claim 8, wherein said control signals comprise information on peak power, pulse duration, spot size, wavelength, and repetition rate of the laser.
